(19) United States
(12) Patent Application Publication
(10) Pub. No.: US 2025/0046691 A1
(43) Pub. Date: Feb. 6, 2025

(54) SEMICONDUCTOR PACKAGE AND MANUFACTURING METHOD FOR THE SAME

(71) Applicant: Samsung Electronics Co., Ltd., Suwon-si (KR)

(72) Inventors: Ji Hwang KIM, Suwon-si (KR); Kyung Don MUN, Suwon-si (KR); Sangjin BAEK, Suwon-si (KR); Hyeonjeong HWANG, Suwon-si (KR)

(73) Assignee: Samsung Electronics Co., Ltd., Suwon-si (KR)

(21) Appl. No.: 18/544,707

(22) Filed: Dec. 19, 2023

(30) Foreign Application Priority Data
Aug. 1, 2023 (KR) 10-2023-0100637

(51) Int. Cl. H01L 23/498; H01L 23/00; H01L 23/31; H01L 23/522; H01L 25/00; H01L 25/065

(52) U.S. Cl. CPC H01L 23/49822; H01L 23/3128; H01L 23/5226; H01L 24/16; H01L 24/32; H01L 24/73; H01L 25/0657; H01L 25/50; H01L 2224/16225; H01L 2224/32225; H01L 2224/73204; H01L 2225/06517; H01L 2924/181

(57) ABSTRACT

A semiconductor package includes: a first redistribution line structure; a first semiconductor chip on one surface of the first redistribution line structure; a first conductive bump between, and connecting, the first redistribution line structure and the first semiconductor chip; a first encapsulant encapsulating at least a portion of the first semiconductor chip; a second semiconductor chip on another, opposite surface of the first redistribution line and including a through via; a second conductive bump between, and connecting, the first redistribution line structure and the second semiconductor chip; a second encapsulant encapsulating at least a portion of the second semiconductor chip; and a second redistribution line structure on the second encapsulant. The second encapsulant covers at least a portion of a surface of the second semiconductor chip facing the second redistribution line structure.

### CROSS-REFERENCE TO RELATED APPLICATION

This application claims priority to and the benefit of Korean Patent Application No. 10-2023-0100637 filed at the Korean Intellectual Property Office on Aug. 1, 2023, the entire contents of which are incorporated herein by reference.

### BACKGROUND

### (a) Field

The present inventive concepts relate to semiconductor packages and manufacturing methods for the same.

### (b) Description of the Related Art

Chiplet technology designed to overcome problems such as production cost, production difficulty, and yield deterioration of monolithic technology that integrates various functions into one chip to produce the chip.

The chiplet technology is a technology that produces one package by connecting several semiconductor chips with different functions to each other through high-speed interconnect. The chips included in the semiconductor package to which the chiplet technology is applied may be responsible for various functions such as a function of a logic chip such as a central processing unit (CPU) or a graphics processing unit (GPU), a function of a memory chip, and the like.

In order to minimize yield loss of the semiconductor chip in the chiplet technology using the plurality of semiconductor chips, it is desirable to select a known good die (KGD) during a manufacturing process and perform a subsequent process on only the selected die.

An electronic element such as a capacitor may be included within the semiconductor package to improve a power integrity (PI) characteristic of the semiconductor chip. To improve performance of the semiconductor package without a significant increase in difficulty of the manufacturing process or manufacturing cost, efficient disposition between the semiconductor chip and the electronic element is required.

### SUMMARY

Some example embodiments of the present inventive concepts provide a semiconductor package with reduced yield loss and/or a manufacturing method for the same.

Some example embodiments of the present inventive concepts provide a semiconductor package having an improved power characteristic (e.g., reduced power consumption, improved power consumption efficiency, etc.) without a significant increase in difficulty of a manufacturing process or manufacturing cost and/or a manufacturing method for the semiconductor package.

A semiconductor package according to some example embodiments of the present inventive concepts may include a semiconductor package comprising a first redistribution line structure; a first semiconductor chip on one surface of the first redistribution line structure; a first conductive bump between the first redistribution line structure and the first semiconductor chip to connect the first redistribution line structure and the first semiconductor chip; a first encapsulant encapsulating at least a portion of the first semiconductor chip; a second semiconductor chip on another surface of the first redistribution line structure that is opposite to the one surface of the first redistribution line structure, the second semiconductor chip including a through via; a second conductive bump between the first redistribution line structure and the second semiconductor chip to connect the first redistribution line structure and the second semiconductor chip; a second encapsulant encapsulating at least a portion of the second semiconductor chip; and a second redistribution line structure on the second encapsulant. The second encapsulant may cover at least a portion of a surface of the second semiconductor chip facing the second redistribution line structure.

The first semiconductor chip may include a first connecting pad, and the first connecting pad may face the first redistribution line structure.

The second semiconductor chip may include a second connecting pad, and the second connecting pad may face the first redistribution line structure.

The second semiconductor chip may include a second connecting pad, and the second connecting pad may face the second redistribution line structure.

The semiconductor package may further include a first conductive post penetrating the second encapsulant and electrically connects the first redistribution line structure and the second redistribution line structure.

The semiconductor package may further include: a third redistribution line structure on the first encapsulant; and a second conductive post penetrating the first encapsulant and electrically connects the first redistribution line structure and the third redistribution line structure.

The semiconductor package may further include a via penetrating a portion of the second encapsulant to electrically connect the second semiconductor chip and the second redistribution line structure.

The through via may penetrate at least a portion of the second semiconductor chip to further penetrate a portion of the second encapsulant, and may electrically connect the second semiconductor chip and the second redistribution line structure.

The semiconductor package may further include: an electronic element disposed above the other surface of the first redistribution line structure to be spaced apart from the second semiconductor chip; and a third conductive bump disposed between the first redistribution line structure and the electronic element to connect the first redistribution line structure and the electronic element.

The first redistribution line structure may include a redistribution line layer exposed to a surface of the first redistribution line structure facing the second semiconductor chip.

The first encapsulant may cover a side surface of the first semiconductor chip and an opposite surface of a surface facing the first redistribution line structure.

A semiconductor package according to some example embodiments of the present inventive concepts may include a first redistribution line structure; a first semiconductor chip that on one surface of the first redistribution line structure to be electrically connected to the first redistribution line structure; a first encapsulant on the one surface of the first redistribution line structure to encapsulate at least a portion of the first semiconductor chip; a second redistribution line structure on the first encapsulant; a first conductive post penetrating the first encapsulant and electrically connects the first redistribution line structure and the second redistribution line structure; a second semiconductor chip on another surface of the first redistribution line structure that is opposite to the one surface of the first redistribution line structure to be electrically connected to the first redistribution line structure, the second semiconductor chip including a through via; an electronic element on the other surface of the first redistribution line structure, the electronic element spaced apart from the second semiconductor chip and electrically connected to the first redistribution line structure; a second encapsulant on the other surface of the first redistribution line structure to encapsulate at least a portion of each of the second semiconductor chip and the electronic element; a third redistribution line structure on the second encapsulant; and a second conductive post penetrating the second encapsulant and electrically connects the first redistribution line structure and the third redistribution line structure. The second encapsulant may cover a surface of each of the second semiconductor chip and the electronic element facing the third redistribution line structure.

At least a particular portion of the first semiconductor chip and at least a portion of the electronic element may overlap each other on a plane.

The through via may electrically connect the first redistribution line structure and the third redistribution line structure.

A manufacturing method for the semiconductor package according to some example embodiments of the present inventive concepts may include preparing a first redistribution line structure on a first carrier film; disposing a first semiconductor chip on one surface of the first redistribution line structure; forming a carriage structure based on encapsulating the first semiconductor chip with a first encapsulant; disposing the carriage structure on a second carrier film so that a particular surface of the carriage structure is disposed on the second carrier film, the particular surface is opposite to a surface of the carriage structure on which the first carrier film of the carriage structure is disposed; peeling off the first carrier film; disposing a second semiconductor chip including a through via on another surface of the first redistribution line structure opposite to the one surface of the first redistribution line structure; encapsulating the second semiconductor chip with a second encapsulant; forming a second redistribution line structure on the second encapsulant to be connected to the second semiconductor chip; and peeling off the second carrier film.

The manufacturing method may further include performing an electrical inspection between the first redistribution line structure and the first semiconductor chip.

The manufacturing method may further include: forming a first conductive post on the one surface of the first redistribution line structure; and forming a third redistribution line structure on the first encapsulant to be connected to the first conductive post. The carriage structure may include the first conductive post and the third redistribution line structure.

The manufacturing method may further include performing an electrical inspection between the first redistribution line structure, the first conductive post, the third redistribution line structure, and the first semiconductor chip.

The manufacturing method may further include forming a second conductive post on the other surface of the first redistribution line structure. In the forming of the second redistribution line structure, the second redistribution line structure may be formed to be connected to the second conductive post.

The manufacturing method may further include disposing an electronic element on the other surface of the first redistribution line structure such that the electronic element is spaced apart from the second semiconductor chip.

According to some example embodiments of the present inventive concepts, a semiconductor package with reduced yield loss and a manufacturing method for the same may be provided.

According to some example embodiments of the present inventive concepts, a semiconductor package having an improved power characteristic without a significant increase in difficulty of a manufacturing process or manufacturing cost and a manufacturing method for the semiconductor package may be provided.

### BRIEF DESCRIPTION OF THE DRAWINGS

FIG. 1 is a schematic cross-sectional view of a semiconductor package according to some example embodiments of the present inventive concepts.

FIG. 2 is a schematic cross-sectional view of a semiconductor package according to some example embodiments of the present inventive concepts.

FIG. 3 is a schematic cross-sectional view of a semiconductor package according to some example embodiments of the present inventive concepts.

FIG. 4 is a schematic cross-sectional view of a semiconductor package according to some example embodiments of the present inventive concepts.

FIG. 5 is a schematic cross-sectional view of a semiconductor package according to some example embodiments of the present inventive concepts.

FIGS. 6A, 6B, 6C, 6D, 6E, 6F, 6G, 6H, 6I, 6J, 6K, and 6L are schematic manufacturing process views of the semiconductor package according to some example embodiments of the present inventive concepts.

### DETAILED DESCRIPTION

The present inventive concepts will be described more fully hereinafter with reference to the accompanying drawings, in which some example embodiments of the inventive concepts are shown. As those skilled in the art would realize, the example embodiments may be modified in various different ways, all without departing from the spirit or scope of the present inventive concepts.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In a similar sense, this includes being “physically connected” as well as being “electrically connected”. In some example embodiments, unless explicitly described to the contrary, the word “comprise” and variations such as “comprises” or “comprising” will be understood to imply the inclusion of stated elements but not the exclusion of any other elements.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on (e.g., above) or below (e.g., beneath) the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In some example embodiments, throughout the specification, sequential numbers such as 1st and 2nd are used to distinguish a certain component from another component that is the same or similar to the same, and are not necessarily intended to refer to a specific component. Accordingly, a component referred to as a first component in a specific portion of the specification may be referred to as a second component in another portion of the specification.

In some example embodiments, throughout the specification, a singular reference to a component includes references to a plurality of these components, unless specifically stated to the contrary. For example, “a redistribution line layer” may be used to mean not only one redistribution line layer but also a plurality of redistribution line layers such as two, three, or more redistribution line layers.

In some example embodiments, throughout the specification, references to one surface and the other surface are intended to distinguish different surfaces from each other, and are not necessarily intended to limit it to a specific surface. Accordingly, a surface referred to as one surface in a specific portion of the specification may be referred to as the other surface in another portion of the specification.

will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of +10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., +10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., +10%) around the stated elements and/or properties thereof.

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Hereinafter, a semiconductor package according to some example embodiments will be described with reference to the drawings.

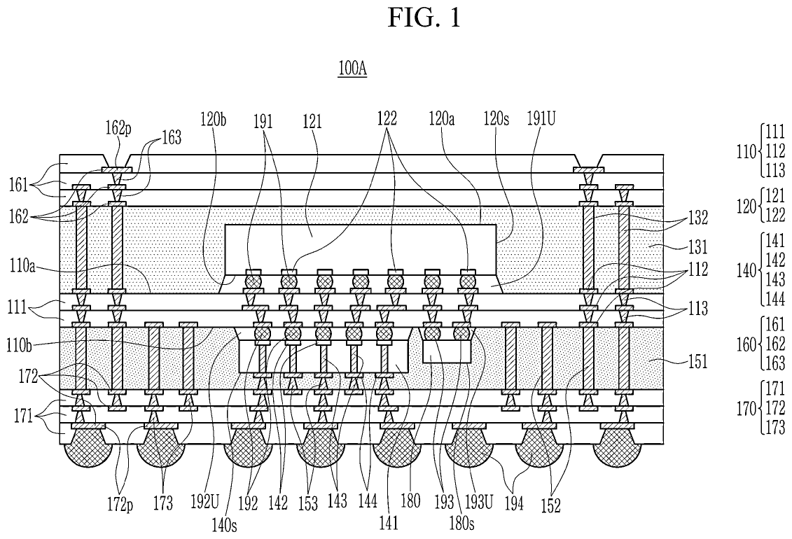

FIG. 1 is a schematic cross-sectional view of the semiconductor package according to some example embodiments of the present inventive concepts.

Referring to FIG. 1, the semiconductor package 100A according to some example embodiments of the present inventive concepts may include a first redistribution line structure 110 (or a first rewiring structure), a first semiconductor chip 120 disposed on (e.g., above, beneath, etc.) one surface 110a (e.g., a first surface) of the first redistribution line structure 110, a first conductive bump 191 disposed between the first redistribution line structure 110 and the first semiconductor chip 120 to connect the first redistribution line structure 110 and the first semiconductor chip 120, a first encapsulant 131 that encapsulates at least a portion of the first semiconductor chip 120, a second redistribution line structure 160 disposed on the first encapsulant 131, a second semiconductor chip 140 disposed on (e.g., above, beneath, etc.) another surface 110b (e.g., a second surface) of the first redistribution line structure 110 that is opposite to the one surface 110a of the first redistribution line structure 110, the second semiconductor chip 140 including a through via 143 (or a penetrating via), a second conductive bump 192 disposed between the first redistribution line structure 110 and the second semiconductor chip 140 to connect the first redistribution line structure 110 and the second semiconductor chip 140, a second encapsulant 151 encapsulating at least a portion of the second semiconductor chip 140, and a third redistribution line structure 170 disposed on the second encapsulant 151. The second encapsulant 151 may cover (e.g., directly contact) at least a portion of a surface 140s of the second semiconductor chip 140 that is facing (e.g., opposing) the third redistribution line structure 170. In some example embodiments, the semiconductor package 100A may further include a connection structure 194 disposed on the third redistribution line structure 170. In some example embodiments, the semiconductor package 100A may include the third redistribution line structure 170 and may omit the second redistribution line structure 160. In some example embodiments, the third redistribution line structure 170 may be referred to as a second redistribution line structure that is on the second encapsulant 151. In some example embodiments, the second redistribution line structure 160 may be referred to as a third redistribution line structure that is on the first encapsulant 131.

In some example embodiments, the semiconductor package 100A may further include at least one of a first conductive post 132 that penetrates the first encapsulant 131 and electrically connects the first redistribution line structure 110 and the second redistribution line structure 160, a second conductive post 152 that penetrates the second encapsulant 151 and electrically connects the first redistribution line structure 110 and the third redistribution line structure 170, and a via 153 that penetrates a portion of the second encapsulant 151 and electrically connects the second semiconductor chip 140 and the third redistribution line structure 170. In some example embodiments, the second conductive post 152 may be referred to as a first conductive post. In some example embodiments, the first conductive post 132 may be referred to as a second conductive post.

In some example embodiments, the semiconductor package 100A may further include an electronic element 180 disposed on (e.g., above, beneath, etc.) the other surface 110b of the first redistribution line structure 110 to be spaced apart from the second semiconductor chip 140. In this case, the semiconductor package 100A may further include a third conductive bump 193 that is disposed between the first redistribution line structure 110 and the electronic element 180 to connect the first redistribution line structure 110 and the electronic element 180.

Hereinafter, each configuration of the semiconductor package 100A will be described in detail. In the following description, a direction from the first semiconductor chip 120 to the second semiconductor chip 140 will be described as a lower side, and a direction from the second semiconductor chip 140 to the first semiconductor chip 120 will be described as an upper side. However, it will be understood that example embodiments are not limited thereto.

The first redistribution line structure 110 may include an insulating layer 111, a redistribution line layer 112, and a via 113. The number (e.g., quantity) of the insulating layer 111, the redistribution line layer 112, and the via 113 is not particularly limited, and there may be a single or a plurality of the insulating layers 111, the redistribution line layers 112, and/or the vias 113.

For example, the insulating layer 111 may include a photo-imageable dielectric (PID). The photo-imageable dielectric (PID) may include a polyimide-based photosensitive polymer, a novolac-based photosensitive polymer, polybenzoxazole, a silicone-based polymer, an acrylate-based polymer, or an epoxy-based polymer. In some example embodiments, the insulating layer 111 may be formed of an inorganic dielectric material such as silicon nitride, silicon oxide, or the like.

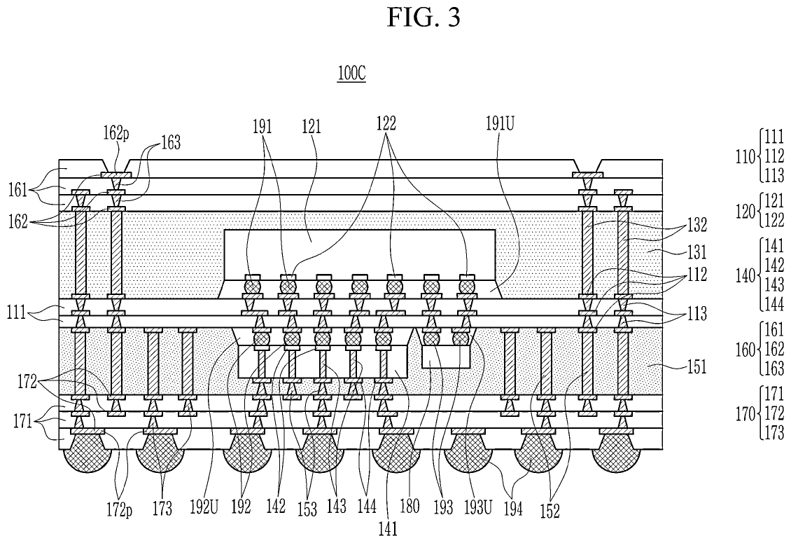

The first redistribution line structure 110 may include the redistribution line layer 112 exposed to a surface (e.g., the other surface 110b) facing the second semiconductor chip 140 of the first redistribution line structure 110. As shown in FIG. 1, the redistribution line layer 112 exposed to the surface facing the second semiconductor chip 140 may be buried in the insulating layer 111 to be exposed to one surface of the insulating layer 111. As shown in FIG. 3, the redistribution line layer 112 exposed on the surface facing the second semiconductor chip 140 may be disposed on the insulating layer 111. Accordingly, the second semiconductor chip 140 and the electronic element 180 may be disposed above the redistribution line layer 112 exposed to the surface facing the second semiconductor chip 140 to be connected to the first redistribution line structure 110.

For example, as shown in FIG. 1, each of a plurality of redistribution line layers 112 except for the redistribution line layer 112 disposed at a lowermost side may be disposed on each of the insulating layers 111. In some example embodiments, the redistribution line layer 112 disposed at the lowermost side may be buried in the insulating layer 111 disposed at the lowermost side to be exposed to one surface of the insulating layer 111. In other words, an embedded trace substrate (ETS) structure may be applied to the first redistribution line structure 110, and it may be possible to implement a fine circuit pattern and reduce a thickness in the first redistribution line structure 110. A formation material of the redistribution line layer 112 may include aluminum (Al), copper (Cu), gold (Au), silver (Ag), platinum (Pt), tin (Sn), chromium (Cr), palladium (Pd), lead (Pb), titanium (Ti), or an alloy thereof, but the present inventive concepts are not limited thereto.

The via 113 may penetrate the insulating layer 111 to connect the redistribution line layers 112 disposed in different layers. The via 113 may have a tapered shape whose diameter narrows in a direction from one surface to the other surface, but may also have a circular cylinder shape. For example, as shown in the drawings, the via 113 may have a tapered shape whose diameter narrows in a direction from an upper side to a lower side. A formation material of the via 113 may be the same as a formation material of the redistribution line layer 112, and the via 113 may be integrally formed with the redistribution line layer 112 so that there is no boundary between the via 113 and the redistribution line layer 112.

The first semiconductor chip 120 may be disposed above one surface of the first redistribution line structure 110 to be electrically connected to the first redistribution line structure 110. The first semiconductor chip 120 may include a first body 121 and a first connecting pad 122.

The first body 121 may include a silicon substrate, an integrated circuit layer formed on the silicon substrate, and an interlayer insulating layer covering the integrated circuit layer.

The first connecting pad 122 may electrically connect the first semiconductor chip 120 to the first redistribution line structure 110, and may be formed of a metal such as aluminum (Al), copper (Cu), or the like.

As shown, the first semiconductor chip 120 may be disposed in a face-down form so that the first connecting pad 122 of the first semiconductor chip 120 faces the first redistribution line structure 110. As described below, since the first semiconductor chip 120 is disposed in the face-down form, an electrical inspection of the first semiconductor chip 120 may be possible during a manufacturing process of the semiconductor package 100A.

A type of the first semiconductor chip 120 may not be particularly limited, and the first semiconductor chip 120 may include a logic chip such as a central processing unit (CPU), a graphics processing unit (GPU), an application processor (AP), or the like or a memory chip such as a dynamic random access memory (DRAM), a static random access memory (SRAM), or the like.

The first encapsulant 131 may be disposed on one surface of the first redistribution line structure 110 to encapsulate at least a portion of the first semiconductor chip 120, and may serve to protect the first semiconductor chip 120. The first encapsulant 131 may cover (e.g., directly contact) a side surface 120s of the first semiconductor chip 120 and a surface 120a opposite to a surface 120b of the first semiconductor chip 120 facing the first redistribution line structure 110. However, depending on a design, the first encapsulant 131 may cover only the side surface of the first semiconductor chip 120, and the surface opposite to the surface of the first semiconductor chip 120 facing the first redistribution line structure 110 may be exposed above the first encapsulant 131.

The first encapsulant 131 may be formed of a thermosetting resin such as an epoxy resin, an epoxy molding compound (EMC), or the like. A process of molding the first semiconductor chip 120 with the first encapsulant 131 may be performed by compression molding, transfer molding, or the like.

The first conductive post 132 may penetrate the first encapsulant 131, and may serve to electrically connect the first redistribution line structure 110 and the second redistribution line structure 160. For example, the first conductive post 132 may directly connect a redistribution line pad included in the redistribution line layer 112 disposed at an uppermost side of the first redistribution line structure 110 to a redistribution line pad included in a redistribution line layer 162 disposed at a lowermost side of the second redistribution line structure 160. The first conductive post 132 may have a circular cylinder shape, but may also have a tapered shape whose diameter narrows in a direction from one surface to the other surface. The first conductive post 132 may be formed of a conductive material such as aluminum (Al), copper (Cu), gold (Au), silver (Ag), platinum (Pt), tin (Sn), chromium (Cr), palladium (Pd), lead (Pb), titanium (Ti), or an alloy thereof.

The second semiconductor chip 140 may be disposed above the other surface opposite to the one surface of the first redistribution line structure 110 to be electrically connected to the first redistribution line structure 110. The second semiconductor chip 140 may include a second body 141, a second connecting pad 142, a through via 143, and a through via pad 144.

The second body 141 may include a silicon substrate, an integrated circuit layer formed on the silicon substrate, and an interlayer insulating layer covering the integrated circuit layer.

The second connecting pad 142 may electrically connect the second semiconductor chip 140 to the first redistribution line structure 110, and may be formed of a metal such as aluminum (Al), copper (Cu), or the like.

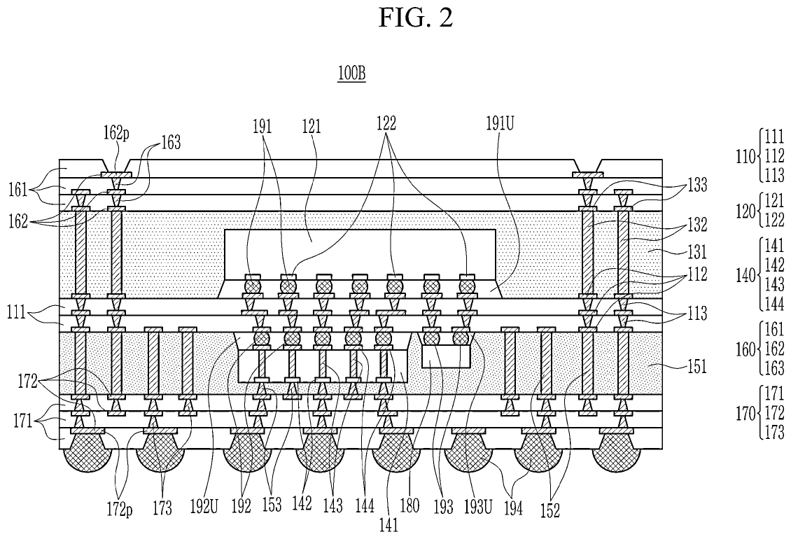

As shown, the second semiconductor chip 140 may be disposed in a face-up form so that the second connecting pad 142 of the second semiconductor chip 140 faces the first redistribution line structure 110. However, as described below in description of FIG. 2, the second semiconductor chip 140 may be disposed in a face-down form so that the second connecting pad 142 faces the third redistribution line structure 170.

The through via 143 may electrically connect the second semiconductor chip 140 to each of the first redistribution line structure 110 and the third redistribution line structure 170, and may also electrically connect the first redistribution line structure 110 to the third redistribution line structure 170. The through via 143 may penetrate at least a portion of the second body 141 in a thickness direction, and may be connected to an integrated circuit layer of the second semiconductor chip 140. For example, as shown in the drawings, the through via 143 may penetrate an entire second body 141 in the thickness direction to be connected to each of the second connecting pad 142 and the through via pad 144. However, the through via 143 may penetrate only a portion (e.g., a limited portion) of the second body 141 in the thickness direction depending on a manufacturing method for the through via 143, and may be indirectly connected to the second connecting pad 142 without directly contacting the second connecting pad 142.

The first semiconductor chip 120 may have a short electrical connection path with the third redistribution line structure 170 through the through via 143, and the number, an area, and the like of the second conductive post 152 for connection between the first redistribution line structure 110 and the third redistribution line structure 170 may be reduced so that miniaturization of the semiconductor package 100A may be possible and/or improved.

The through via pad 144 may be disposed on a surface opposite to a surface where the second connecting pad 142 of the second body 141 is disposed to electrically connect the second semiconductor chip 140 to another component. As shown in the drawings, the through via pad 144 may be disposed on the second body 141, but may be buried in the second body 141 to be exposed to one surface of the second body 141.

A type of the second semiconductor chip 140 may not be particularly limited, and the second semiconductor chip 140 may include a logic chip such as a central processing unit (CPU), a graphics processing unit (GPU), an application processor (AP), or the like or a memory chip such as a dynamic random access memory (DRAM), a static random access memory (SRAM), or the like.

The second semiconductor chip 140 may be a semiconductor chip in an advanced node process, and may be a semiconductor chip with a narrower pitch than that of the first semiconductor chip 120. A width of the second semiconductor chip 140 may be narrower than a width of the first semiconductor chip 120. In some example embodiments, a length of the second semiconductor chip 140 may be shorter than a length of the first semiconductor chip 120. However, the width of the second semiconductor chip 140 may be wider than or equal to the width of the first semiconductor chip 120. In some example embodiments, the length of the second semiconductor chip 140 may be longer than or equal to the length of the first semiconductor chip 120. Here, the width indicates a length in a direction penetrating the page, and the length indicates a length in a direction perpendicular to the width on a plane.

The second encapsulant 151 may be disposed on the other surface 110b of the first redistribution line structure 110 to encapsulate at least a portion of each of the second semiconductor chip 140 and the electronic element 180, and may serve to protect the second semiconductor chip 140 and the electronic element 180. The second encapsulant 151 may cover at least a portion of each surface of the second semiconductor chip 140 and the electronic element 180 (e.g., surface 140s of the second semiconductor chip 140 and surface 180s of the electronic element 180) facing (e.g., opposing) the third redistribution line structure 170. In some example embodiments, the second encapsulant 151 may cover at least a portion of each side surface of the second semiconductor chip 140 and the electronic element 180. However, depending on a design, the second encapsulant 151 may cover only the side surface of the second semiconductor chip 140, and the surface of the second semiconductor chip 140 facing the third redistribution line structure 170 may be exposed above the second encapsulant 151. Similarly, the second encapsulant 151 may cover only the side surface of the electronic element 180, and the surface of the electronic element 180 facing the third redistribution line structure 170 may be exposed above the second encapsulant 151.

The second encapsulant 151 may be formed of a thermosetting resin such as an epoxy resin, an epoxy molding compound (EMC), or the like. A process of molding the second semiconductor chip 140 with the second encapsulant 151 may be performed by compression molding, transfer molding, or the like.

The second conductive post 152 may penetrate the second encapsulant 151, and may serve to electrically connect the first redistribution line structure 110 and the third redistribution line structure 170. For example, the second conductive post 152 may directly connect a redistribution line pad included in the redistribution line layer 112 disposed at a lowermost side of the first redistribution line structure 110 to a redistribution line pad included in a redistribution line layer 172 disposed at an uppermost side of the third redistribution line structure 170. The second conductive post 152 may have a circular cylinder shape, but may also have a tapered shape whose diameter narrows in a direction from one surface to the other surface. The second conductive post 152 may be formed of a conductive material such as aluminum (Al), copper (Cu), gold (Au), silver (Ag), platinum (Pt), tin (Sn), chromium (Cr), palladium (Pd), lead (Pb), titanium (Ti), or an alloy thereof.

The via 153 may penetrate a portion of the second encapsulant 151 to electrically connect the second semiconductor chip 140 and the third redistribution line structure 170. For example, the via 153 may directly connect the through via pad 144 of the second semiconductor chip 140 to the redistribution line layer 172 disposed at the uppermost side of the third redistribution line structure 170. The via 153 may have a tapered shape whose diameter narrows in a direction from the third redistribution line structure 170 to the second semiconductor chip 140, but may also have a circular cylinder shape. The via 153 may be formed of a conductive material such as aluminum (Al), copper (Cu), gold (Au), silver (Ag), platinum (Pt), tin (Sn), chromium (Cr), palladium (Pd), lead (Pb), titanium (Ti), or an alloy thereof.

Similar to the first redistribution line structure 110, the second redistribution line structure 160 may include an insulating layer 161, the redistribution line layer 162, and a via 163.

The redistribution line layer 162 disposed at a lowermost side among redistribution line layers 162 may be disposed on the first encapsulant 131 to be buried in the insulating layer 161 disposed at a lowermost side among insulating layers 161. The redistribution line layer 162 disposed at an uppermost side among the redistribution line layers 162 may include a connecting pad 162p exposed through an opening of the insulating layer 161 disposed at an uppermost side among the insulating layers 161. A configuration such as a semiconductor chip or another semiconductor package may be disposed on the semiconductor package 100A, and the configuration may be connected to the semiconductor package 100A through the connecting pad 162p.

In addition to the above description, a description of each of the insulating layer 111, the redistribution line layer 112, and the via 113 included in the first redistribution line structure 110 may be equally applied to a description of each of the insulating layer 161, the redistribution line layer 162, and the via 163 included in the second redistribution line structure 160 unless there is a particularly contradictory description. Thus, a detailed description thereof will be omitted.

Similar to the first redistribution line structure 110, the third redistribution line structure 170 may include an insulating layer 171, a redistribution line layer 172, and a via 173.

The redistribution line layer 172 disposed at an uppermost side among redistribution line layers 172 may be disposed on the second encapsulant 151 to be buried in the insulating layer 171 disposed at an uppermost side among insulating layers 171. The redistribution line layer 172 disposed at a lowermost side among the redistribution line layers 172 may include a connecting pad 172p exposed through an opening of the insulating layer 171 disposed at a lowermost side among the insulating layers 171. The connection structure 194 may be disposed on the connecting pad 172p, and the semiconductor package 100A may be connected to another component such as a printed circuit board or the like through the connection structure 194 and the connecting pad 172p.

A description of each of the insulating layer 111, the redistribution line layer 112, and the via 113 included in the first redistribution line structure 110 may be equally applied to a description of each of the insulating layer 171, the redistribution line layer 172, and the via 173 included in the third redistribution line structure 170 unless there is a particularly contradictory description. Thus, a detailed description thereof will be omitted.

The electronic element 180 may be disposed above the other surface 110b of the first redistribution line structure 110 to be spaced apart from the second semiconductor chip 140, and may be electrically connected to the first redistribution line structure 110. In some example embodiments, the electronic element 180 may be connected to the first semiconductor chip 120 through the first redistribution line structure 110. Depending on a design, the electronic element 180 may be connected to the second semiconductor chip 140 through the first redistribution line structure 110.

The electronic element 180 may be disposed to face at least a portion of the first semiconductor chip 120 with the first redistribution line structure 110 interposed therebetween, so that, as shown in at least FIG. 1, at least a portion (e.g., a particular portion) of the first semiconductor chip 120 and at least a portion of the electronic element 180 may overlap each other on a plane (e.g., overlap each other in a vertical direction as shown in FIG. 1 and extending perpendicular to the one surface 110a and/or the other surface 110b). The electronic element 180 may be disposed to face the first semiconductor chip 120 with the first redistribution line structure 110 interposed therebetween, so that the electronic element 180 may overlap some regions of the first semiconductor chip 120 on a plane. Since the electronic element 180 is disposed to overlap the first semiconductor chip 120, an electrical connection path between the electronic elements 180 and the first semiconductor chip 120 may be reduced or minimized, and the first semiconductor chip 120 may have an excellent electrical power characteristic (e.g., reduced power consumption, improved power consumption efficiency, etc.) due to the short electrical connection path resulting from the electronic element 180 being on (e.g., directly on) and electrically connected to the first redistribution line structure 110 to face (e.g., vertically overlap) the first semiconductor chip 120 across the first redistribution line structure 110.

The electronic element 180 may be a passive element such as a capacitor (e.g., a multi-layer ceramic capacitor (MLCC)), a resistor, an inductor, or the like, or may be an active element such as a semiconductor chip.

The first conductive bump 191 may be disposed between the first redistribution line structure 110 and the first semiconductor chip 120 to serve to connect the first redistribution line structure 110 and the first semiconductor chip 120.

Similarly, the second conductive bump 192 may be disposed between the first redistribution line structure 110 and the second semiconductor chip 140 to serve to connect the first redistribution line structure 110 and the second semiconductor chip 140.

In some example embodiments, the third conductive bump 193 may be disposed between the first redistribution line structure 110 and the electronic element 180 to serve to connect the first redistribution line structure 110 and the electronic element 180.

A conductive material may be used as a formation material for each of the first conductive bump 191, the second conductive bump 192, and the third conductive bump 193, and for example, a formation material of each of the first conductive bump 191, the second conductive bump 192, and the third conductive bump 193 may include copper (Cu), palladium (Pd), bismuth (Bi), antimony (Sb), tin (Sn), silver (Ag), or an alloy thereof such as a tin-silver (SnAg) alloy.

In order to distribute a stress applied to the first conductive bump 191, an underfill 191U surrounding the first conductive bump 191 may be filled. The underfill 191U may fill a space between the first redistribution line structure 110 and the first semiconductor chip 120, and in some cases, may extend to a side surface of the first semiconductor chip 120 to cover a portion of the side surface of the first semiconductor chip 120.

Similarly, to distribute a stress applied to the second conductive bump 192, an underfill 192U surrounding the second conductive bump 192 may be filled. The underfill 192U may fill a space between the first redistribution line structure 110 and the second semiconductor chip 140, and in some cases, may extend to a side surface of the second semiconductor chip 140 to cover a portion of the side surface of the second semiconductor chip 140.

In some example embodiments, in order to distribute a stress applied to the third conductive bump 193, an underfill 193U surrounding the third conductive bump 193 may be filled. The underfill 193U may fill a space between the first redistribution line structure 110 and the electronic element 180, and in some cases, may extend to a side surface of the electronic element 180 to cover a portion of the side surface of the electronic element 180.

The underfill 191U, 192U, or 193U may be formed of an underfill resin such as an epoxy resin, and may include a silica filler, a flux, or the like.

The connection structure 194 is disposed on the third redistribution line structure 170, and is a configuration for connecting the semiconductor package 100A to another configuration such as a printed circuit board or the like. The connection structure 194 may fill the opening of the insulating layer 171 disposed at the lowermost side among the insulating layers 171, and may extend onto the insulating layer 171 disposed at the lowermost side. The connection structure 194 may be in contact with and directly connected to the connecting pad 172p exposed through the insulating layer 171. A formation material of the connection structure 194 may include copper (Cu), palladium (Pd), bismuth (Bi), antimony (Sb), tin (Sn), silver (Ag), or an alloy thereof such as a tin-silver (SnAg) alloy. For example, the connection structure 194 may be a solder ball.

In some example embodiments, when a semiconductor package is manufactured, a lower semiconductor chip (e.g., second semiconductor chip 140) and, if necessary, an electronic element (e.g., electronic element 180) such as a capacitor or the like may be mounted on a front side redistribution line (FRDL) structure (e.g., the third redistribution line structure 170) so that the mounted lower semiconductor chip and the mounted electronic element encapsulated with a lower encapsulant (e.g., second encapsulant 151) are packaged, a mid redistribution line (MRDL) structure (e.g., first redistribution line structure 110) may be formed on the lower encapsulant, an upper semiconductor chip (e.g., first semiconductor chip 120) may be mounted on the mid redistribution line structure (e.g., first redistribution line structure 110) so that the mounted upper semiconductor chip encapsulated with an upper encapsulant (e.g., first encapsulant 131) is packaged, and then a back side redistribution line (BRDL) structure (e.g., second redistribution line structure 160) may be formed on the upper encapsulant. In this case, since an electrical inspection of the upper semiconductor chip (e.g., first semiconductor chip 120) is not possible before the semiconductor package is completed, a subsequent process may be performed on a defective upper semiconductor chip so that yield loss of the lower semiconductor chip may occur.

In some example embodiments, the electronic element is connected to the upper semiconductor chip through the front side redistribution line structure, a conductive post, and the mid redistribution line structure using the conductive post that penetrates the lower encapsulant, so that it has a long electrical connection path with the upper semiconductor chip. In some example embodiments, it is possible to form a through via in the electronic element and connect the electronic element to the mid redistribution line structure, but a manufacturing process becomes complicated and manufacturing cost increases.

In some example embodiments, according to the present inventive concepts, the first semiconductor chip 120 may first be disposed above the first redistribution line structure 110, an electrical inspection may be performed between the first semiconductor chip 120 and the first redistribution line structure 110 and between the first conductive post 132 and the second redistribution line structure 160, and then a subsequent process may be performed only for an intermediate package (e.g., including the first semiconductor chip 120 and omitting the second semiconductor chip 140) that passes the electrical inspection. Therefore, according to the present inventive concepts, it is possible to prevent yield loss of the second semiconductor chip 140 that may occur when the subsequent process is performed on a defective intermediate package. If the second semiconductor chip 140 is the semiconductor chip in the advanced node process, reducing, minimizing, or preventing the yield loss of the second semiconductor chip 140 may be particularly advantageous in terms of manufacturing cost or the like.

However, if necessary, the second semiconductor chip 140 may first be disposed above the first redistribution line structure 110 before the first semiconductor chip 120 is disposed, an electrical inspection may be performed between the second semiconductor chip 140, the first redistribution line structure 110, the second conductive post 152, and the third redistribution line structure 170, and then a subsequent process may be performed only for an intermediate package that passes the electrical inspection. In other words, according to the present inventive concepts, the electrical inspection may first be performed on one of the first semiconductor chip 120 and the second semiconductor chip 140, and then the subsequent process may be performed.

In some example embodiments, according to the present inventive concepts, the electronic element 180 may be disposed on (e.g., above), for example directly on, the first redistribution line structure 110 rather than the third redistribution line structure 170, so that the electronic element 180 has a short electrical connection path with the first semiconductor chip 120. Therefore, the first semiconductor chip may have an excellent power characteristic (e.g., reduced power consumption, improved power consumption efficiency, etc.) due to the short electrical connection path resulting from the electronic element 180 being on (e.g., directly on) and electrically connected to the first redistribution line structure 110. In some example embodiments, since no additional process such as forming a through via is required to connect the electronic element 180 and the first semiconductor chip 120, an increase in difficulty of a manufacturing process or manufacturing cost is not required.

FIG. 2 is a schematic cross-sectional view of a semiconductor package according to some example embodiments of the present inventive concepts.

Referring to FIG. 2, a mounting direction of the second semiconductor chip 140 of the semiconductor package 100B is different from that of the semiconductor package 100A according to some example embodiments, including the example embodiments shown in FIG. 1. Specifically, in the semiconductor package 100B, the second connecting pad 142 may be disposed in a face-down form to face the third redistribution line structure 170. In this case, the second connecting pad 142 of the second semiconductor chip 140 may be connected to the third redistribution line structure 170 through the via 153. In some example embodiments, the through via pad 144 of the second semiconductor chip 140 may be connected to the first redistribution line structure 110 through the second conductive bump 192.

Since a description of other configurations is the same as that specifically described in the semiconductor package 100A according to some example embodiments of the present inventive concepts, a detailed description of the configurations is omitted.

FIG. 3 is a schematic cross-sectional view of a semiconductor package according to some example embodiments of the present inventive concepts.

Referring to FIG. 3, the first redistribution line structure 110 of the semiconductor package 100C may not have an ETS structure. For example, as shown in the drawings, the redistribution line layer 112 may be disposed on each of the insulating layers 111, and the redistribution line layer 112 disposed at a lowermost side may also be disposed on the insulating layer 111 disposed at a lowermost side. In some example embodiments, the via 113 disposed at a lowermost side may have a tapered shape whose diameter narrows in a direction from an upper side to a lower side.

Since a description of other configurations is the same as that specifically described in the semiconductor package 100A according to some example embodiments of the present inventive concepts, a detailed description of the configurations is omitted.

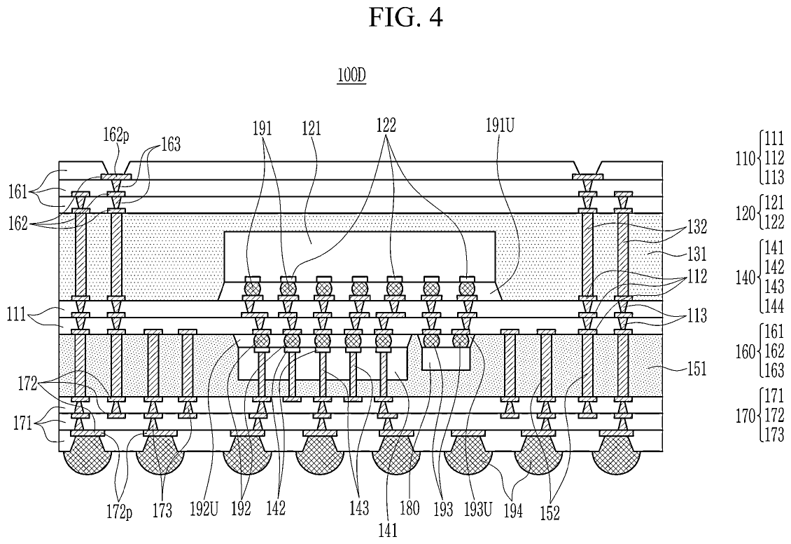

FIG. 4 is a schematic cross-sectional view of a semiconductor package according to some example embodiments of the present inventive concepts.

Referring to FIG. 4, the second semiconductor chip 140 of the semiconductor package 100D may not include the through via pad 144. In some example embodiments, the through via 143 may penetrate at least a portion of the second semiconductor chip 140 (specifically, the second body 141), which may be referred to herein as at least partially penetrating the second semiconductor chip 140, may further penetrate a portion of the second encapsulant 151, and may electrically connect the second semiconductor chip 140 and the third redistribution line structure 170. As a result, the semiconductor package 100D may not include the via 153 as a separate element from the through via 143.

Since a description of other configurations is the same as that specifically described in the semiconductor package 100A according to some example embodiments of the present inventive concepts, a detailed description of the configurations is omitted.

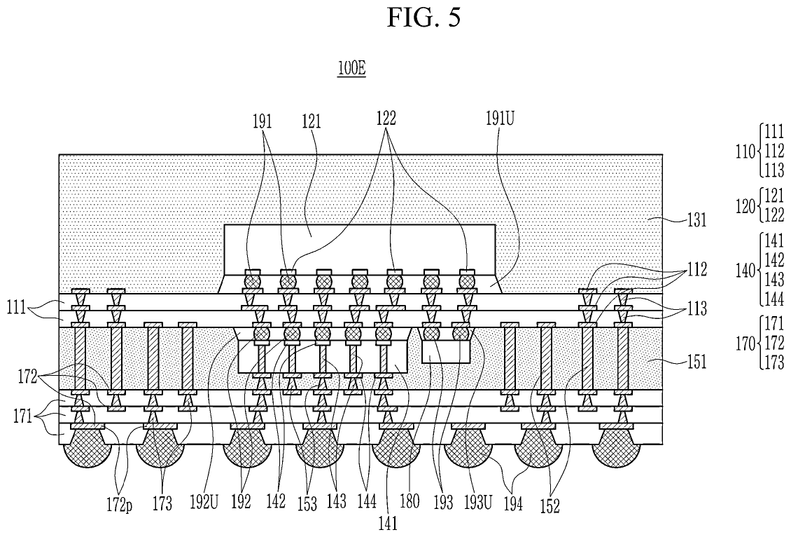

FIG. 5 is a schematic cross-sectional view of a semiconductor package according to some example embodiments of the present inventive concepts.

Referring to FIG. 5, the semiconductor package 100E may not include the first conductive post 132 and the second redistribution line structure 160. If another component is not disposed above or on the semiconductor package 100E, the first conductive post 132 and the second redistribution line structure 160 that are components for connecting the other component to the semiconductor package 100E, may not be included.

Since a description of other configurations is the same as that specifically described in the semiconductor package 100A according to some example embodiments of the present inventive concepts, a detailed description of the configurations is omitted.

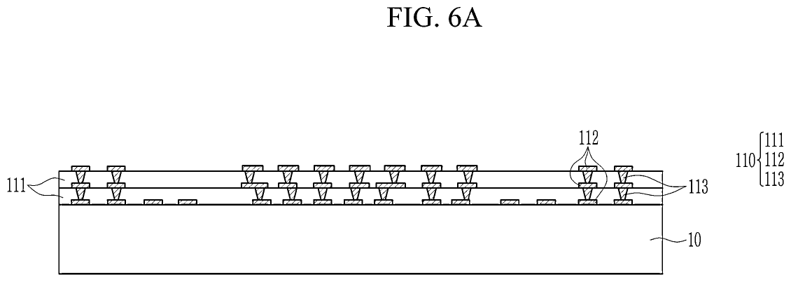

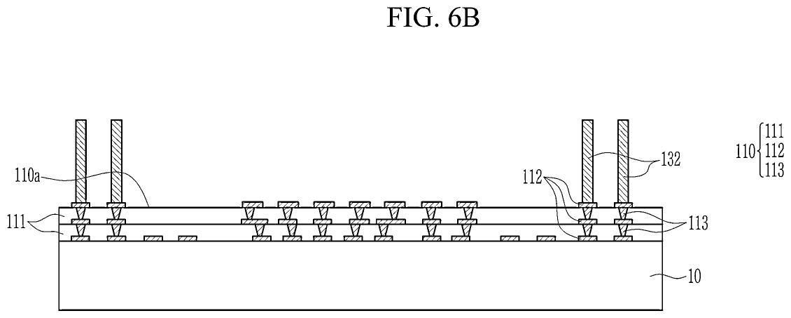

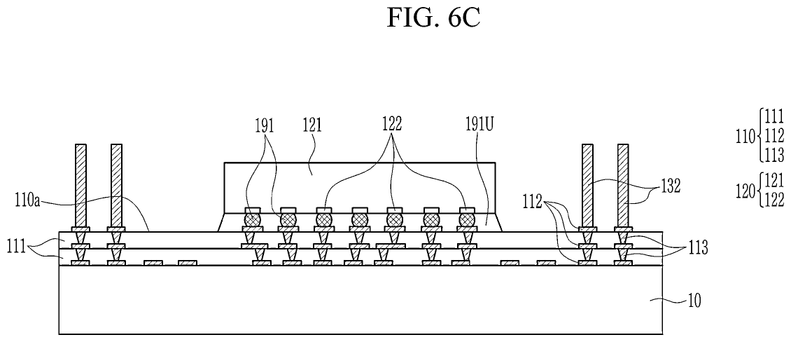

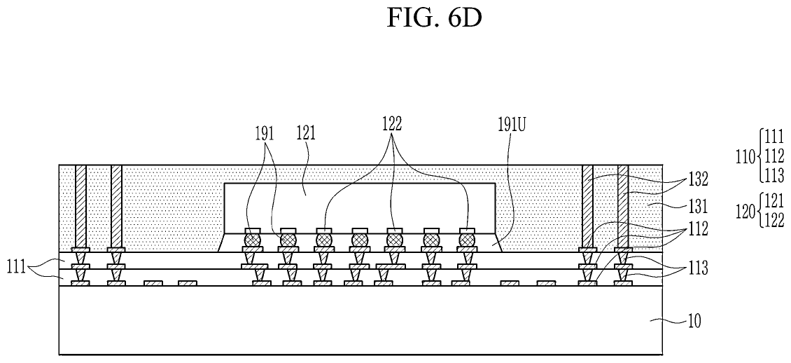

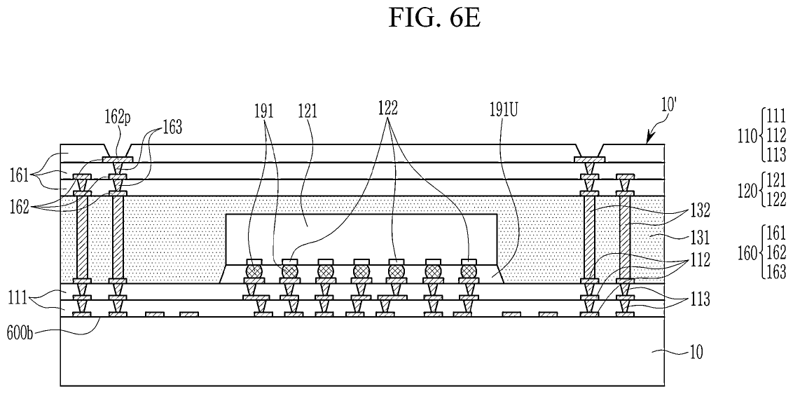

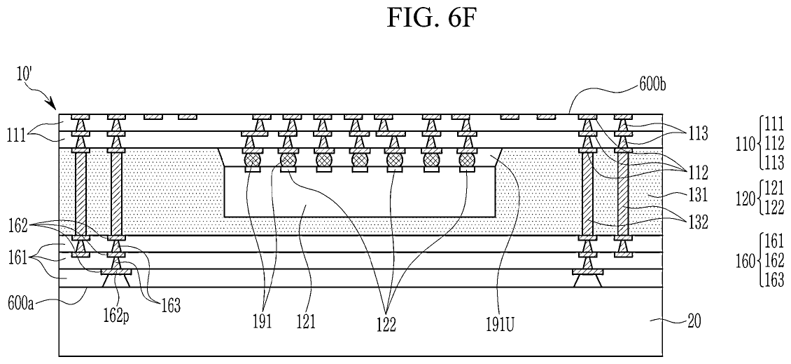

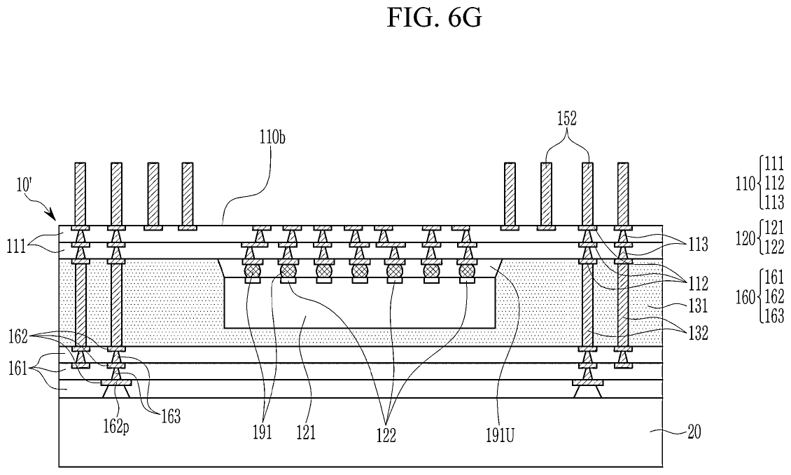

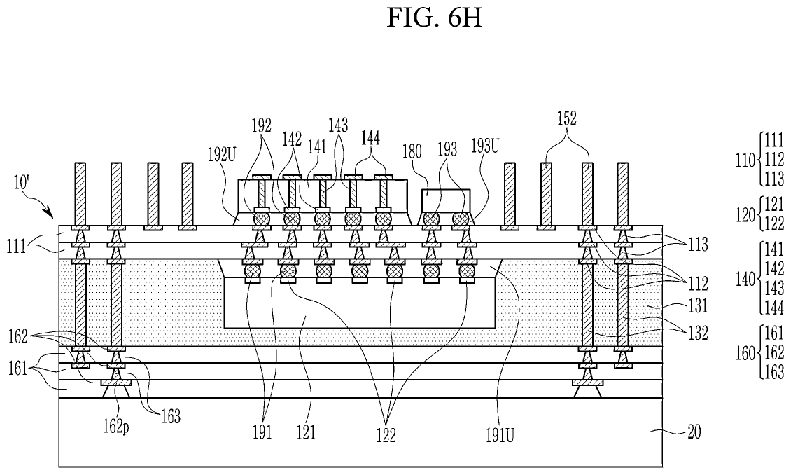

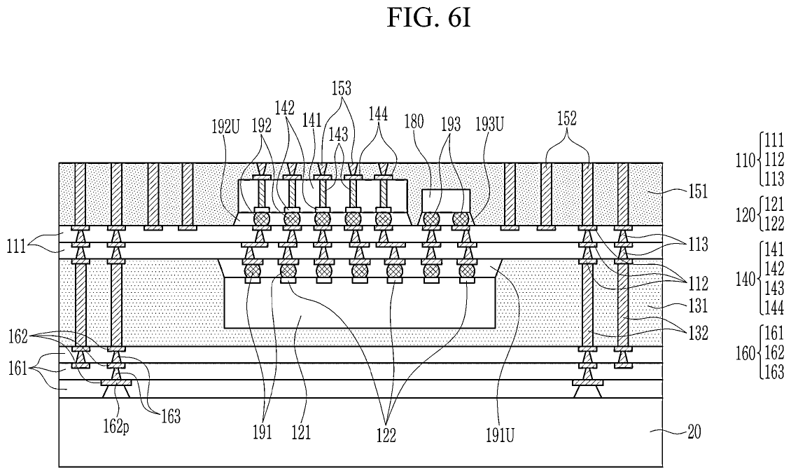

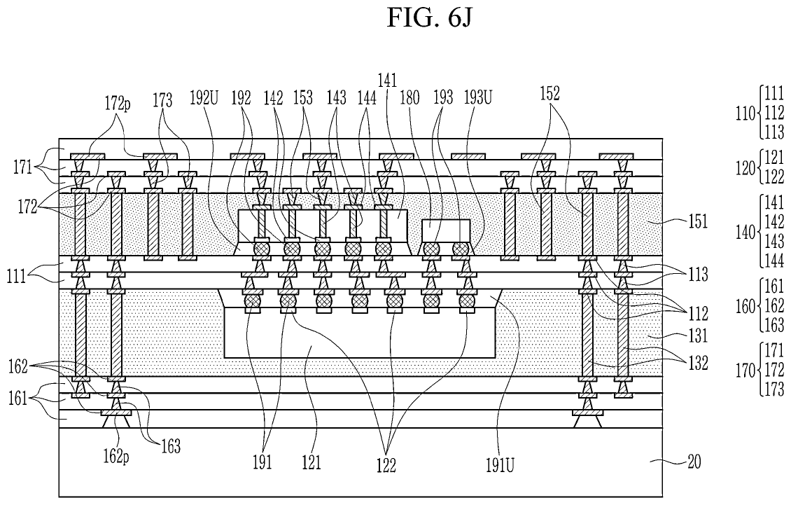

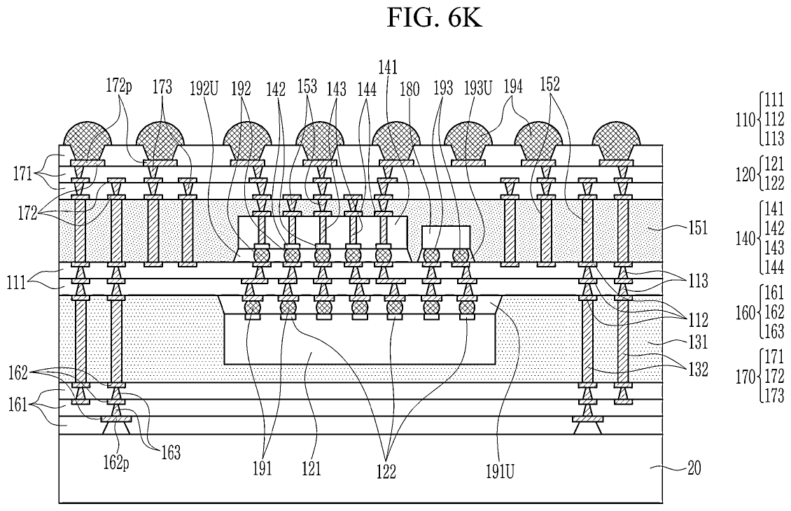

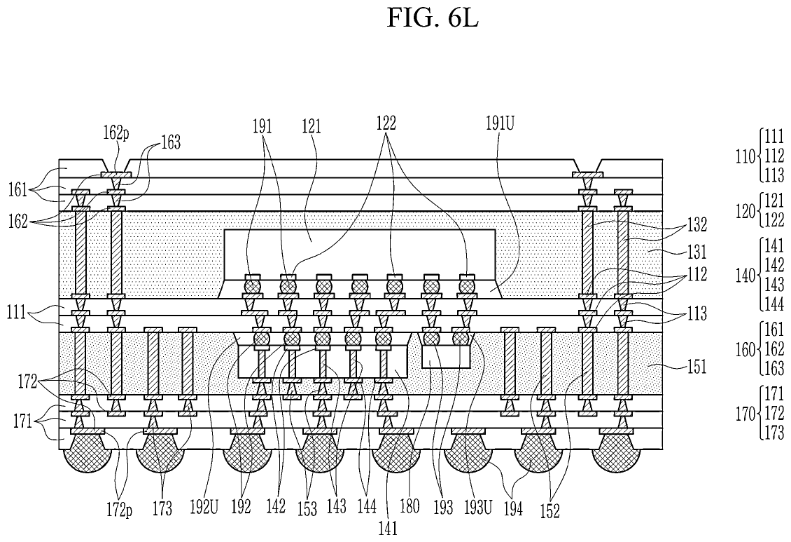

FIGS. 6A, 6B, 6C, 6D, 6E, 6F, 6G, 6H, 6I, 6J, 6K, and 6L are schematic manufacturing process views of the semiconductor package according to some example embodiments of the present inventive concepts.

Referring to the drawings, a manufacturing method for the semiconductor package may include preparing the first redistribution line structure 110 on a first carrier film 10, forming the first conductive post 132 on one surface of the first redistribution line structure 110, disposing the first semiconductor chip 120 on (e.g., above, beneath, etc.) the one surface 110a of the first redistribution line structure 110, encapsulating the first semiconductor chip 120 and the first conductive post 132 with the first encapsulant 131, forming a carriage structure 10′ based on forming the second redistribution line structure 160 on the first encapsulant 131 to be connected to the first conductive post 132, disposing the carriage structure 10′ on a second carrier film 20, peeling off the first carrier film 10, forming the second conductive post 152 on the other surface 110b of the first redistribution line structure 110, disposing the second semiconductor chip 140 including the through via 143 on (e.g., above, beneath, etc.) the other surface 110b of the first redistribution line structure 110, encapsulating the second semiconductor chip 140 and the second conductive post 152 with the second encapsulant 151, forming the third redistribution line structure 170 on the second encapsulant 151 to be connected to the second semiconductor chip 140 and the second conductive post 152, and peeling off the second carrier film 20.

If necessary, the manufacturing method for the semiconductor package may further include disposing the electronic element 180 on (e.g., above, beneath, etc.) the other surface 110b of the first redistribution line structure 110 to be spaced apart from the second semiconductor chip 140. In this case, the second encapsulant 151 may encapsulate the electronic element 180 together with the second semiconductor chip 140 and the second conductive post 152.

In some example embodiments, the manufacturing method for the semiconductor package may further include performing an electrical inspection on the first semiconductor chip 120. Specifically, the manufacturing method for the semiconductor package may further include performing the electrical inspection between the first redistribution line structure 110, the first conductive post 132, the second redistribution line structure 160, and the first semiconductor chip 120.

In some example embodiments, when the semiconductor package has a structure of the semiconductor package 100E shown in FIG. 5, a step of forming the first conductive post 132 and the second redistribution line structure 160 may not be necessary. In this case, a process including the first conductive post 132 and the second redistribution line structure 160 in the above-described process will be modified and implemented. For example, the carriage structure 10′ may not include the first conductive post 132 and the second redistribution line structure 160, the first semiconductor chip 120 may be disposed above one surface of the first redistribution line structure 110 prepared on the first carrier film 10, and the carriage structure 10′ may be formed by encapsulating the first semiconductor chip 120 with the first encapsulant 131. In some example embodiments, the step of performing the electrical inspection on the first semiconductor chip 120 may be a step of performing the electrical inspection between the first redistribution line structure 110 and the first semiconductor chip 120.

Similarly, the semiconductor package may not include the second conductive post 152, and a step of forming the second conductive post 152 may not be necessary. In this case, a process including the second conductive post 152 in the above-described process will be modified and implemented.

Hereinafter, each process of the manufacturing method for the semiconductor package according to some example embodiments of the present inventive concepts will be described in detail.

Referring to FIG. 6A, the step of preparing the first redistribution line structure 110 on the first carrier film 10 may be performed based on sequentially forming the redistribution line layer 112, the insulating layer 111, and the via 113 on the first carrier film 10. However, when the first redistribution line structure 110 has the structure shown in FIG. 3, the redistribution line layer 112 and the via 113 disposed at a lowermost side may be formed after the first carrier film 10 is peeled off.

Referring to FIGS. 6B and 6C, in the step of forming the first conductive post 132 on the one surface 110a of the first redistribution line structure 110 and the step of disposing the first semiconductor chip 120 above the one surface 110a of the first redistribution line structure 110, each of the first conductive post 132 and the first semiconductor chip 120 may be disposed above or on the redistribution line pad included in the redistribution line layer 112 disposed at the uppermost side of the first redistribution line structure 110. In this case, the first semiconductor chip 120 may be disposed above or on the redistribution line pad using the first conductive bump 191.

Order of the step of forming the first conductive post 132 on the one surface of the first redistribution line structure 110 and the step of disposing the first semiconductor chip 120 above the one surface 110a of the first redistribution line structure 110 is not particularly limited. Accordingly, the step of forming the first conductive post 132 on the one surface 110a of the first redistribution line structure 110 may be performed before the step of disposing the first semiconductor chip 120 on (e.g., above) the one surface 110a of the first redistribution line structure 110. However, the step of forming the first conductive post 132 on the one surface 110a of the first redistribution line structure 110 may also be performed after the step of disposing the first semiconductor chip 120 above the one surface 110a of the first redistribution line structure 110.

Referring to FIG. 6D, in the step of encapsulating the first semiconductor chip 120 and the first conductive post 132 with the first encapsulant 131, the encapsulating may be performed by compression molding, transfer molding, or the like. In some example embodiments, the manufacturing method for the semiconductor package may further include a step of grinding the first encapsulant 131 so that the first conductive post 132 is exposed to one surface of the first encapsulant 131.

Referring to FIG. 6E, a step of forming the second redistribution line structure 160 on the first encapsulant 131 may be performed (e.g., to at least partially form a carriage structure 10′) based on sequentially forming the redistribution line layer 162, the insulating layer 161, and the via 163 on the first encapsulant 131. The redistribution line layer 162 formed on the first encapsulant 131 may include a redistribution line pad formed on the first conductive post 132 to be directly connected to the first conductive post 132.

In some example embodiments, the insulating layer 161 disposed at an uppermost side of the semiconductor package may have an opening for exposing the connecting pad 162p. Therefore, the manufacturing method for the semiconductor package according to some example embodiments may further include forming the opening at the insulating layer 161 to expose the connecting pad 162p.

Referring to FIG. 6F, the step of disposing the carriage structure 10′ on the second carrier film 20 is performed so that a surface 600a of the carriage structure 10′ (e.g., a particular surface of the carriage structure), opposite to a surface 600b of the carriage structure 10′ on which the first carrier film 10 is disposed, is disposed on the second carrier film 20. Therefore, the first redistribution line structure 110 is exposed through the step of peeling off the first carrier film 10.

The step of performing the electrical inspection on the first semiconductor chip 120 may be performed on the second carrier film 20 after the first carrier film 10 is peeled off (e.g., peeled off from the carriage structure 10′). The first redistribution line structure 110 is exposed through the step of peeling off the first carrier film 10, so that the electrical inspection between the first redistribution line structure 110, the first conductive post 132, the second redistribution line structure 160, and the first semiconductor chip 120 is possible.

Referring to FIGS. 6G and 6H, in the step of forming the second conductive post 152 on the other surface 110b of the first redistribution line structure 110, the step of disposing the second semiconductor chip 140, and the step of disposing the electronic element 180, each of the second conductive post 152, the second semiconductor chip 140, and the electronic element 180 may be disposed above or on a redistribution line pad included in the redistribution line layer 112 exposed to the other surface of the first redistribution line structure 110. In this case, each of the second semiconductor chip 140 and the electronic element 180 may be disposed above or on the redistribution line pad using the second conductive bump 192 and the third conductive bump 193. The operations shown in FIGS. 6G and/or 6H may be selectively performed based on a determination, resulting from performing the electrical inspection on the carriage structure 10′ shown in at least FIG. 6F, that the carriage structure 10′ including a known good die (KGD). As a result, the first formation of the second semiconductor chip 140 and the electronic element 180 above or on the redistribution line pad using the second conductive bump 192 and the third conductive bump 193 may be limited to being performed using a carriage structure 10′ that is determined to be a known good die (KGD) due to electrical inspection of at least the first semiconductor chip 120. As a result, because the formation of the second semiconductor chip 140 and the electronic element 180 on the carriage structure 10′ may be limited to carriage structures 10′ including known good dies (KGD) containing the first semiconductor chip 120, the yield of semiconductor packages including the first and second semiconductor chips 120 and 140 may be improved.

In some example embodiments, the order of the step of forming the second conductive post 152 on the other surface 110b of the first redistribution line structure 110, the step of disposing the second semiconductor chip 140, and the step of disposing the electronic element 180 is not particularly limited. For example, the second conductive post 152 may be formed on the other surface 110b of the first redistribution line structure 110, the second semiconductor chip 140 may be disposed, and then the electronic element 180 may be disposed. As another example, the second semiconductor chip 140 may be disposed above the other surface 110b of the first redistribution line structure 110, the electronic element 180 may be disposed, and then the second conductive post 152 may be formed.

Referring to FIG. 6I, in the step of encapsulating the second semiconductor chip 140 and the second conductive post 152 with the second encapsulant 151, the encapsulating may be performed by compression molding, transfer molding, or the like. When the semiconductor package includes the electronic element 180, the second encapsulant 151 may encapsulate the electronic element 180 together with the second semiconductor chip 140 and the second conductive post 152. In some example embodiments, the manufacturing method for the semiconductor package may further include a step of grinding the second encapsulant 151 so that the second conductive post 152 is exposed to one surface of the second encapsulant 151.

Referring to FIG. 6J, the step of forming the third redistribution line structure 170 on the second encapsulant 151 may be performed by sequentially forming the redistribution line layer 172, the insulating layer 171, and the via 173 on the second encapsulant 151. The redistribution line layer 172 formed on the second encapsulant 151 may include a redistribution line pad formed above or on the second conductive post 152 to be connected to the second conductive post 152.

The manufacturing method for the semiconductor package may further include forming the via 153 that penetrates the second encapsulant 151 to be connected to the second semiconductor chip 140 in order to connect the third redistribution line structure 170 to the second semiconductor chip 140. In some example embodiments, the third redistribution line structure 170 may be formed to be connected to the via 153, and the redistribution line layer 172 formed on the second encapsulant 151 may include a redistribution line pad formed above or on the via 153 to be connected thereto. Accordingly, the second semiconductor chip 140 and the third redistribution line structure 170 may be connected through the via 153.

Referring to FIG. 6K, the manufacturing method for the semiconductor package may further include a step of disposing the connection structure 194 on the third redistribution line structure 170. The connection structure 194 may be disposed on the connecting pad 172p exposed through the opening of the insulating layer 171. Accordingly, the manufacturing method for the semiconductor package according to some example embodiments may form the opening of the insulating layer 171 to expose the connecting pad 172p.

Referring to FIG. 6L, the second carrier film 20 may be peeled off (e.g., peeled off of the carriage structure 10′, peeled off of the second redistribution line structure 160, etc.) to complete the semiconductor package according to some example embodiments of the present inventive concepts.

It is obvious that a description of each component included in the semiconductor package manufactured by the manufacturing method for the semiconductor package according to some example embodiments of the present inventive concepts may be equally applied to the description of each component of the semiconductor package according to some example embodiments of the present inventive concepts.

While the inventive concepts have been described in connection with what is presently considered to be practical example embodiments, it is to be understood that the inventive concepts are not limited to such example embodiments, but, on the contrary, are intended to cover various modifications and equivalent arrangements included within the spirit and scope of the appended claims.

What is claimed is:

1. A semiconductor package comprising:
a first redistribution line structure;
a first semiconductor chip on one surface of the first redistribution line structure;
a first conductive bump between the first redistribution line structure and the first semiconductor chip to connect the first redistribution line structure and the first semiconductor chip;
a first encapsulant encapsulating at least a portion of the first semiconductor chip;
a second semiconductor chip on another surface of the first redistribution line structure that is opposite to the one surface of the first redistribution line structure, the second semiconductor chip including a through via;
a second conductive bump between the first redistribution line structure and the second semiconductor chip to connect the first redistribution line structure and the second semiconductor chip;
a second encapsulant encapsulating at least a portion of the second semiconductor chip; and
a second redistribution line structure on the second encapsulant,
wherein the second encapsulant covers at least a portion of a surface of the second semiconductor chip facing the second redistribution line structure.

2. The semiconductor package of claim 1, wherein the first semiconductor chip includes a first connecting pad, and the first connecting pad faces the first redistribution line structure.

3. The semiconductor package of claim 2, wherein the second semiconductor chip includes a second connecting pad, and the second connecting pad faces the first redistribution line structure.

4. The semiconductor package of claim 2, wherein the second semiconductor chip includes a second connecting pad, and the second connecting pad faces the second redistribution line structure.

5. The semiconductor package of claim 1, further comprising a first conductive post penetrating the second encapsulant and electrically connecting the first redistribution line structure and the second redistribution line structure.

6. The semiconductor package of claim 5, further comprising:
a third redistribution line structure on the first encapsulant; and
a second conductive post penetrating the first encapsulant and electrically connecting the first redistribution line structure and the third redistribution line structure.

7. The semiconductor package of claim 1, further comprising a via penetrating a portion of the second encapsulant to electrically connect the second semiconductor chip and the second redistribution line structure.

8. The semiconductor package of claim 1, wherein the through via at least partially penetrates the second semiconductor chip to further penetrate a portion of the second encapsulant, and the through via electrically connects the second semiconductor chip and the second redistribution line structure.

9. The semiconductor package of claim 1, further comprising:
an electronic element on the other surface of the first redistribution line structure, the electronic element spaced apart from the second semiconductor chip; and
a third conductive bump between the first redistribution line structure and the electronic element to connect the first redistribution line structure and the electronic element.

10. The semiconductor package of claim 1, wherein the first redistribution line structure includes a redistribution line layer exposed to a surface of the first redistribution line structure facing the second semiconductor chip.

11. The semiconductor package of claim 1, wherein the first encapsulant covers a side surface of the first semiconductor chip and an opposite surface of a surface facing the first redistribution line structure.

12. A semiconductor package, comprising:
a first redistribution line structure;
a first semiconductor chip that on one surface of the first redistribution line structure to be electrically connected to the first redistribution line structure;
a first encapsulant on the one surface of the first redistribution line structure to encapsulate at least a portion of the first semiconductor chip;
a second redistribution line structure on the first encapsulant;
a first conductive post penetrating the first encapsulant and electrically connecting the first redistribution line structure and the second redistribution line structure;
a second semiconductor chip on another surface of the first redistribution line structure that is opposite to the one surface of the first redistribution line structure to be electrically connected to the first redistribution line structure, the second semiconductor chip including a through via;
an electronic element on the other surface of the first redistribution line structure, the electronic element spaced apart from the second semiconductor chip and electrically connected to the first redistribution line structure;
a second encapsulant on the other surface of the first redistribution line structure to encapsulate at least a portion of each of the second semiconductor chip and the electronic element;
a third redistribution line structure on the second encapsulant; and
a second conductive post penetrating the second encapsulant and electrically connecting the first redistribution line structure and the third redistribution line structure,
wherein the second encapsulant covers a surface of each of the second semiconductor chip and the electronic element facing the third redistribution line structure.

13. The semiconductor package of claim 12, wherein at least a particular portion of the first semiconductor chip and at least a portion of the electronic element overlap each other on a plane.

14. The semiconductor package of claim 12, wherein the through via electrically connects the first redistribution line structure and the third redistribution line structure.

15. A manufacturing method for a semiconductor package, the method comprising:
preparing a first redistribution line structure on a first carrier film;
disposing a first semiconductor chip on one surface of the first redistribution line structure;
forming a carriage structure based on encapsulating the first semiconductor chip with a first encapsulant;
disposing the carriage structure on a second carrier film so that a particular surface of the carriage structure is disposed on the second carrier film, the particular surface is opposite to a surface of the carriage structure on which the first carrier film of the carriage structure is disposed;
peeling off the first carrier film;
disposing a second semiconductor chip including a through via on another surface of the first redistribution line structure opposite to the one surface of the first redistribution line structure;
encapsulating the second semiconductor chip with a second encapsulant;
forming a second redistribution line structure on the second encapsulant to be connected to the second semiconductor chip; and
peeling off the second carrier film.

16. The manufacturing method of claim 15, further comprising performing an electrical inspection between the first redistribution line structure and the first semiconductor chip.

17. The manufacturing method of claim 15, further comprising:
forming a first conductive post on the one surface of the first redistribution line structure; and
forming a third redistribution line structure on the first encapsulant to be connected to the first conductive post,
wherein the carriage structure further includes the first conductive post and the third redistribution line structure.

18. The manufacturing method of claim 17, further comprising performing an electrical inspection between the first redistribution line structure, the first conductive post, the third redistribution line structure, and the first semiconductor chip.

19. The manufacturing method of claim 15, further comprising forming a second conductive post on the other surface of the first redistribution line structure,
wherein in the forming of the second redistribution line structure, the second redistribution line structure is formed to be connected to the second conductive post.

20. The manufacturing method of claim 15, further comprising disposing an electronic element on the other surface of the first redistribution line structure such that the electronic element is spaced apart from the second semiconductor chip.
